(19) United States
(12) Patent Application Publication
(10) Pub. No.: US 2012/0164815 A1
(43) Pub. Date: Jun. 28, 2012

(54) METHOD OF FORMING ELEMENT ISOLATION LAYER

(75) Inventor: Hidetomo Nishimura, Miyagi (JP)

(73) Assignee: LAPIS SEMICONDUCTOR CO., LTD., TOKYO (JP)

(21) Appl. No.: 13/324,087

(22) Filed: Dec. 13, 2011

(30) Foreign Application Priority Data
Dec. 22, 2010 (JP) 2010-285660

(51) Int. Cl. H01L 21/762

(52) U.S. Cl. 438/424; 257/E21.546

(57) ABSTRACT

There is provided a method of forming an element isolation layer, the method including: forming a pad oxide layer and a nitride layer in succession on a front face of a semiconductor substrate; forming a trench so as to penetrate through the pad oxide layer and the nitride layer and into the semiconductor substrate; forming an in-fill oxide layer so as to fill the trench and cover the nitride layer; polishing the in-fill oxide layer using a first polishing agent so as to leave in-fill oxide layer remaining over the nitride layer; and polishing the in-fill oxide layer using a second polishing agent having a polishing selectivity ratio of the in-fill oxide layer to the nitride layer greater than that of the first polishing agent, so as to expose the nitride layer and flatten the exposed faces of the nitride layer and the in-fill oxide layer.

### CROSS-REFERENCE TO RELATED APPLICATION

This application is based on and claims priority under 35 USC 119 from Japanese Patent Application No. 2010-285660 filed on Dec. 22, 2010, the disclosure of which is incorporated by reference herein.

### BACKGROUND

1. Technical Field

The present invention relates to a method of forming an element isolation layer for electrically isolating plural semiconductor elements formed on a semiconductor substrate from each other.

2. Related Art

Element isolation layers are formed in integrated circuits of semiconductor devices to electrically isolate adjacent semiconductor elements from each other. Known methods for forming such element isolation layers include Local Oxidation of Silicon (LOCOS) methods and Shallow Trench Isolation (STI) methods. Explanation follows regarding each of these methods, with reference to FIG. 1A to FIG. 1E, and FIG. 2A to FIG. 2H. FIG. 1A to FIG. 1E are cross-sections illustrating processes for forming an element isolation layer using a LOCOS method, and FIG. 2A to FIG. 2H are cross-sections illustrating processes for forming an element isolation layer using an STI method.

When forming an element isolation layer with the LOCOS method, a Si substrate 101 is first subjected to heat treatment to react the Si with O₂ at high temperature, thereby growing an SiO₂ layer 102 on the Si substrate 101 (FIG. 1A). SiH₄ and NH₃ gases are then reacted to deposit a Si₃N₄ layer 103 on the SiO₂ layer 102 (FIG. 1B). The Si₃N₄ layer 103 at the region for forming the element isolation layer is then removed while leaving the Si₃N₄ layer 103 remaining in active regions for forming semiconductor elements (FIG. 1C). The Si substrate 101 that has been subjected to the above processes is then exposed to a high temperature oxygen atmosphere, and a SiO₂ layer 102 is grown on the exposed regions where the Si₃N₄ layer 103 has been removed (FIG. 1D). The remaining Si₃N₄ layer 103 and the SiO₂ layer 102 at portions corresponding to the element forming region are then removed, thereby completing the formation of an element isolation layer 104 on the Si substrate 101 (FIG. 1E).

When forming an element isolation layer with an STI method, a first SiO₂ layer 202 and a Si₃N₄ layer 203 are first formed on a Si substrate 201 (FIG. 2A). Then portions of the Si substrate 201, the first SiO₂ layer 202 and the Si₃N₄ layer 203 are removed to form trenches 204 (FIG. 2B). The Si substrate 201 is then placed in a high temperature oxygen atmosphere and a second SiO₂ layer 205 is formed on the side and bottom faces of the trenches 204 (FIG. 2C). A third SiO₂ layer 206 is then in-filled in the trenches 204 using a High Density Plasma-Chemical Vapor Deposition (HDP-CVD) method. The third SiO₂ layer 206 at portions above the Si₃N₄ layer 203 is then removed by a Chemical Mechanical Polishing (CMP) method using the Si₃N₄ layer 203 as a CMP stopper layer, and flattening is performed (FIG. 2E). Portions of the third SiO₂ layer 206 are then removed by etching with hydrogen fluoride (FIG. 2F), and the Si₃N₄ layer 203 is then removed by hot phosphoric acid processing (FIG. 2G). The Si substrate 201 is then flattened by re-etching with hydrogen fluoride, thereby completing the forming of element isolation layers 207 on the Si substrate 201 (FIG. 2H). In the STI method described above, an element isolation layer can be formed with high element isolation properties due to being able to obtain a flatter surface than with a LOCOS method, and so STI methods tend to be employed as the element isolation method in leading edge devices.

Either a silica slurry or a ceria slurry is generally selected as a slurry (polishing agent) in the CMP process of the above STI method. A silica slurry is a polishing agent formed from silica particles made from SiO₂ and so is low cost, however it has only a small ratio of oxide layer polishing speed to nitride layer polishing speed (namely oxide layer to nitride layer polishing selectivity ratio). In contrast thereto, higher cost ceria slurry, a polishing agent configured by mixing ceria particles made from CeO₂ into a dispersion medium (additive agent), has a large oxide layer to nitride layer polishing selectivity ratio. Accordingly either a silica slurry or a ceria slurry is selected in consideration of polishing performance (oxide layer to nitride layer polishing selectivity ratio) against cost.

There is a description of a device and a method employing the above CMP process in, for example, Japanese Patent Application Laid-Open (JP-A) No. 2007-59661.

However an issue arises when attempting to make trenches deeper than usual in order to raise the element isolation performance. In such cases the thickness of the third SiO₂ layer filled in the trench becomes thicker, increasing the amount of the third SiO₂ layer to be polished and leading to a deterioration in controllability of the CMP process.

For example, when polishing with a silica slurry, variation arises in the film thickness of the Si₃N₄ layer remaining on the Si substrate due to the small oxide layer to nitride layer polishing selectivity ratio. More specifically, as shown in FIG. 3A, the remaining film thickness of a Si₃N₄ layer depends on the element region density (%) in a 4 μm×4 μm square, with a lot of the Si₃N₄ layer removed in the portions with low element region density, leading to a portion of the Si substrate that will be an element region also being removed. FIG. 3A is a graph illustrating the remaining film thickness (nm) of Si₃N₄ layer in a specific region of 4 μm×4 μm on a Si substrate when CMP is performed with either a silica slurry (shown with a solid line) or with a ceria slurry (shown with an intermittent line). The ceria slurry employed here has a dispersion medium to ceria particle mixing ratio of about 0.8. The large oxide layer to nitride layer polishing selectivity ratio when polishing is performed using a ceria slurry results in there being little change in the remaining film thickness of the Si₃N₄ layer even when the proportion of the element region density changes.

When polishing with a ceria slurry, whereas there is a large oxide layer to nitride layer polishing selectivity ratio, the polishing speed however falls as the amount to be polished increases, as shown in FIG. 3B. This results in a drop in semiconductor device yield due to defective semiconductor element characteristics caused by SiO₂ layer remaining on the Si₃N₄ layer and leading to insufficient subsequent removal of the Si₃N₄ layer. FIG. 3B is a graph illustrating results of the relationships of polishing speed against amount of SiO₂ layer to be polished for silica slurry (shown with a solid line) and ceria slurry (shown with an intermittent line). It can be seen that the polishing speed does not drop with an increase in amount to be polished for silica slurry.

### SUMMARY

In consideration of the above circumstances, the present invention provides a method of forming an element isolation layer capable of raising the controllability in a polishing process of an insulation layer formed on a semiconductor substrate, and capable of forming an element isolation layer with excellent element isolation properties.

An aspect of the present invention provides a method of forming an element isolation layer, the method including:

forming a pad oxide layer and a nitride layer in succession on a front face of a semiconductor substrate;

forming a trench so as to penetrate through the pad oxide layer and the nitride layer and into the semiconductor substrate;

forming an in-fill oxide layer so as to fill the trench and cover the nitride layer;

polishing the in-fill oxide layer using a first polishing agent so as to leave in-fill oxide layer remaining over the nitride layer; and

polishing the in-fill oxide layer using a second polishing agent having a polishing selectivity ratio of the in-fill oxide layer to the nitride layer greater than the polishing selectivity ratio of the first polishing agent, so as to expose the nitride layer and flatten the exposed faces of the nitride layer and the in-fill oxide layer.

According to the method of forming an element isolation layer of the present invention, the in-fill oxide layer that has been formed so as to fill the trench and cover the nitride layer is polished with a two stage process and the in-fill oxide layer and the nitride layer are subjected to flattening. In the two stage polishing process the polishing agent employed in the later performed polishing process has a polishing selectivity ratio of the in-fill oxide layer to the nitride layer greater than the polishing selectivity ratio of the in-fill oxide layer to the nitride layer with the polishing agent employed in the previously performed polishing process. Such a two stage polishing process enables the in-fill oxide layer to be prevented from remaining after the polishing process has been completed on the nitride layer, and enables prevention of the nitride layer from being worn away. Namely, according to the element isolation layer forming method of the present invention, controllability of the polishing process on the insulator layer formed on the semiconductor substrate is raised, and an element isolation layer with excellent element isolation properties can be formed.

### BRIEF DESCRIPTION OF THE DRAWINGS

Exemplary embodiments of the present invention will be described in detail based on the following figures, wherein:

FIG. 1A to FIG. 1E are cross-sections illustrating processes in a related element isolation layer forming method;

FIG. 2A to FIG. 2H are cross-sections illustrating processes in a related element isolation layer forming method;

FIG. 3A is a graph illustrating relationships of remaining Si₃N₄ film thickness against element region density in a specific region on an Si substrate;

FIG. 3B is a graph illustrating relationships of polishing speed against amount of SiO₂ layer to be polished;

FIG. 4A to FIG. 4I are cross-sections illustrating processes in an element isolation layer forming method according to a first exemplary embodiment;

FIG. 5A to FIG. 5C are cross-sections for explaining another second polishing process according to a third exemplary embodiment employing a ceria slurry; and

FIG. 6 is a graph illustrating relationships of polishing speed against time during polishing, for both a second polishing process according to a third exemplary embodiment and for a related polishing process.

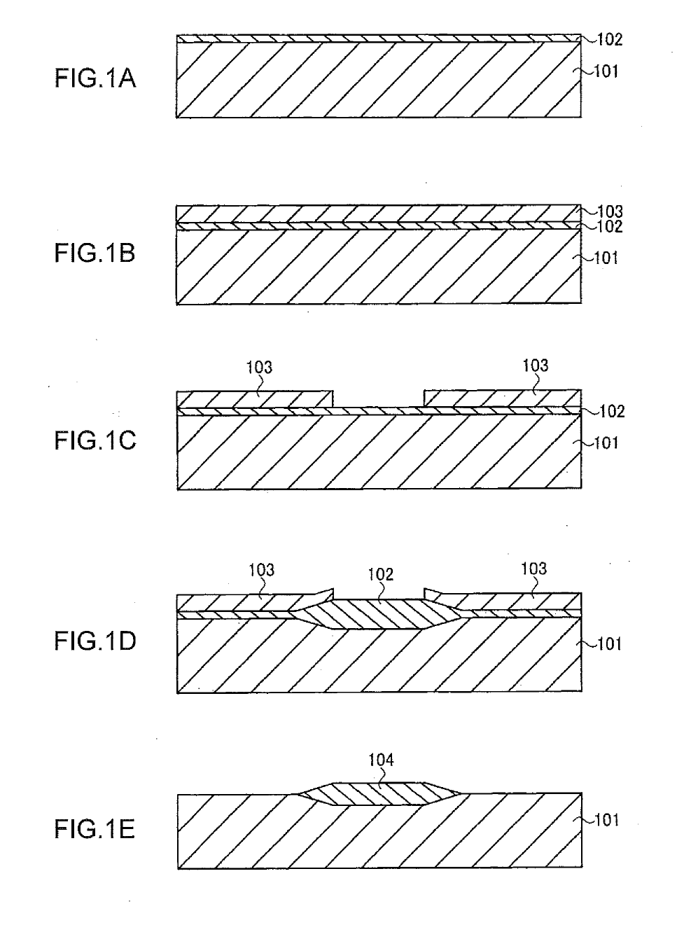

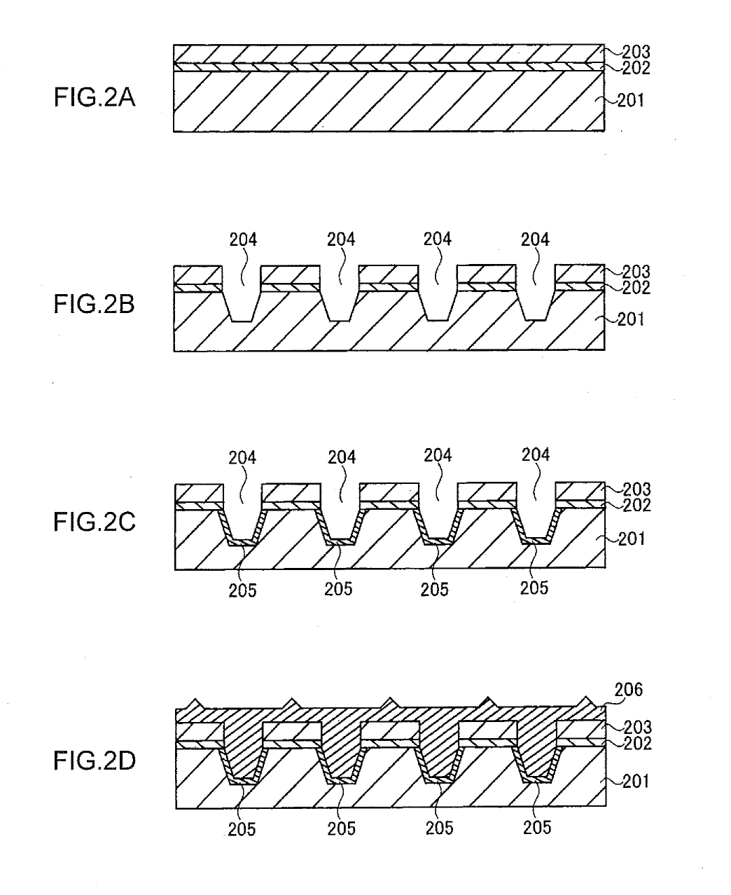

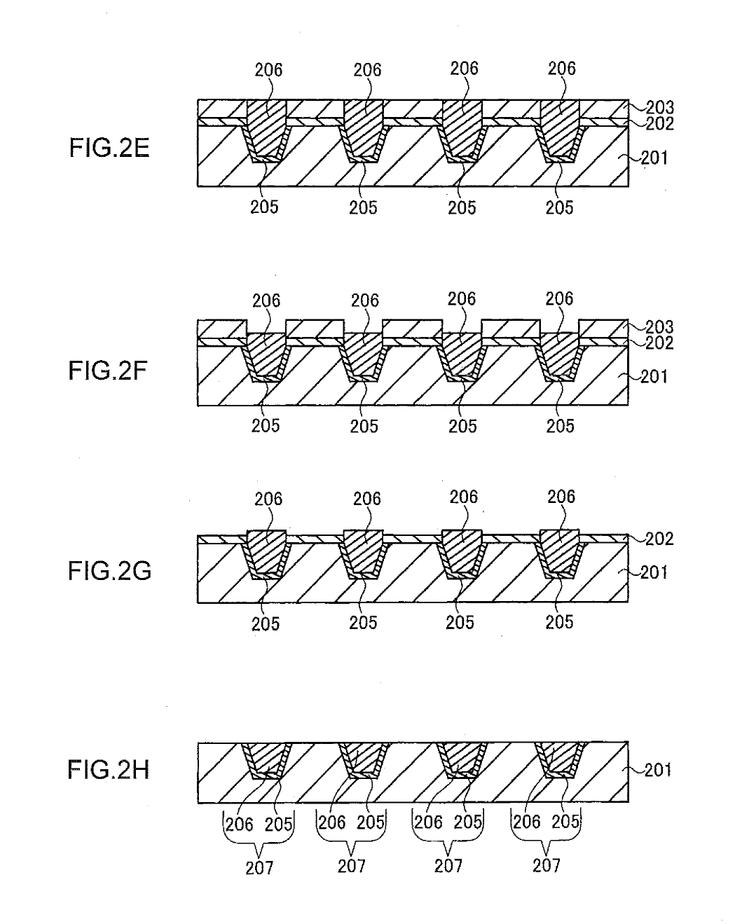

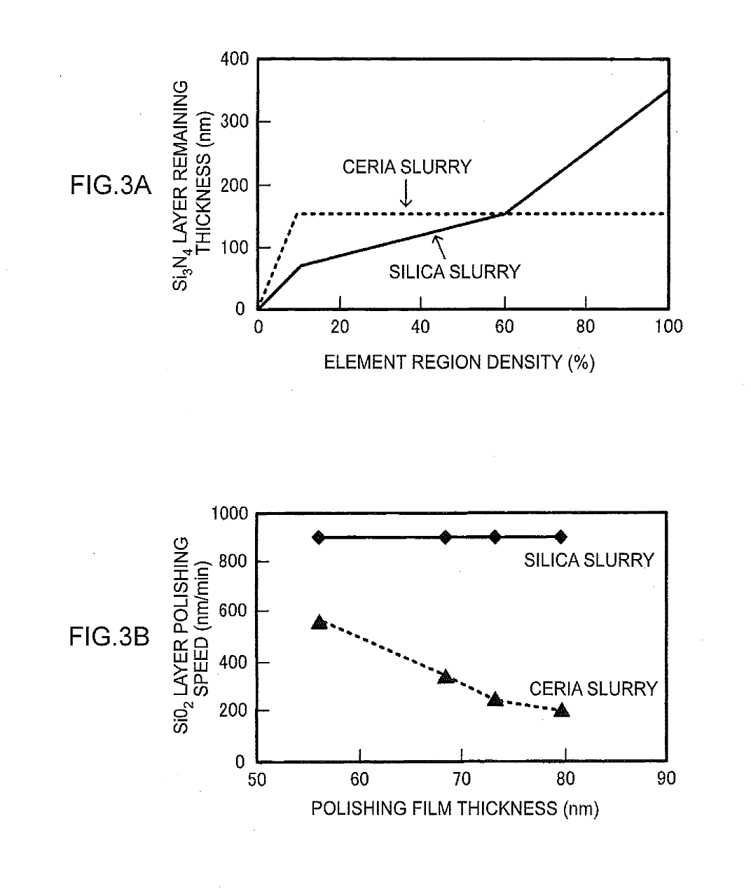

### DETAILED DESCRIPTION

Detailed explanation follows regarding an exemplary embodiment of the present invention, with reference to the drawings.

### First Exemplary Embodiment

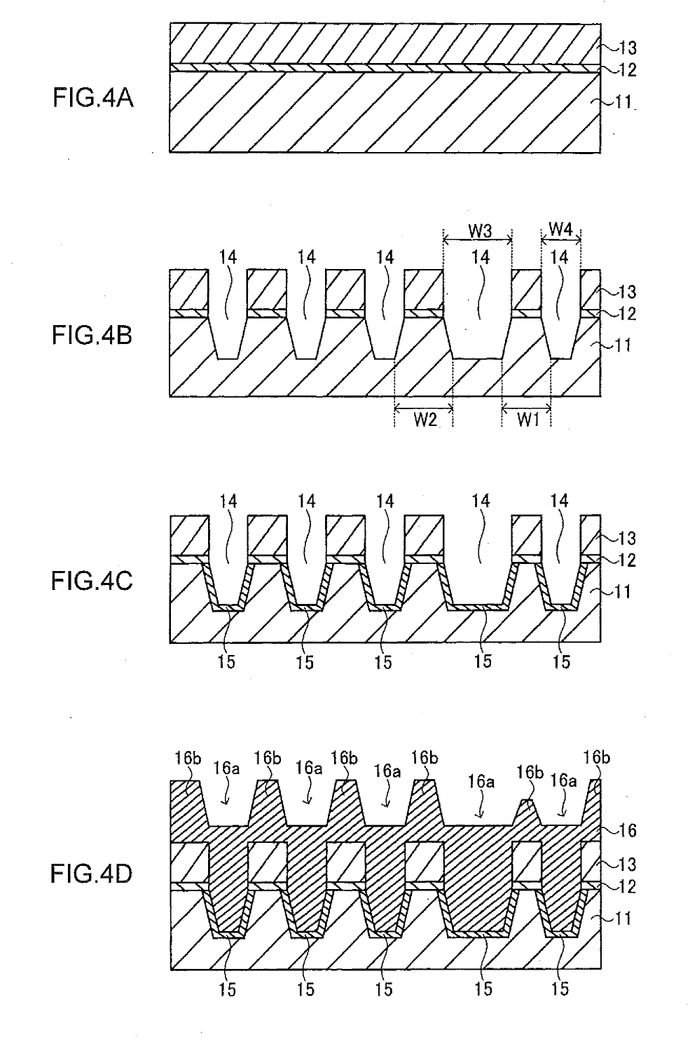

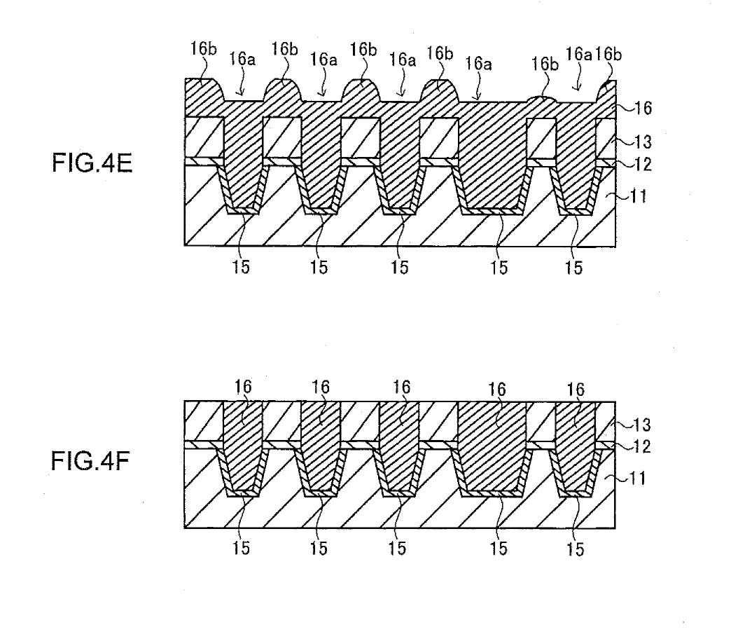

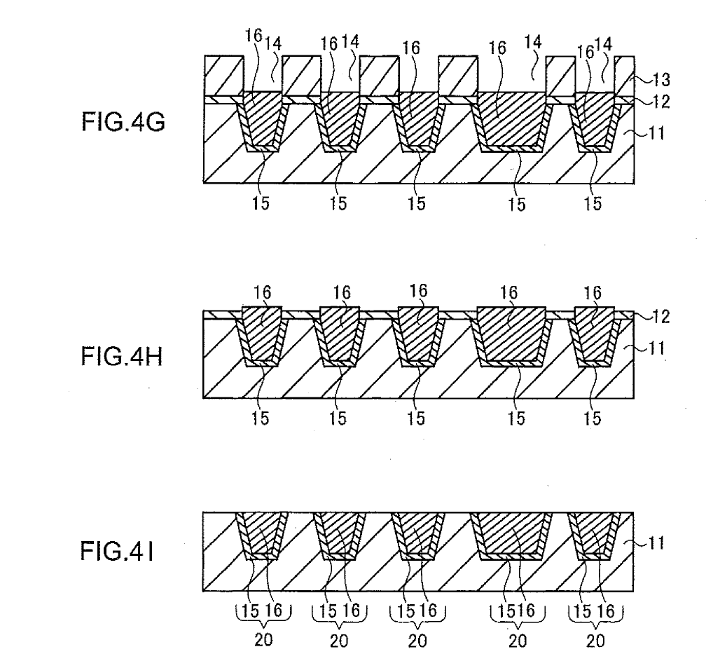

Explanation follows regarding a method of forming an element isolation layer according to a first exemplary embodiment, with reference to FIG. 4A to FIG. 4I. FIG. 4A to FIG. 4I are each cross-sections illustrating processes in an element isolation layer forming method according to the first exemplary embodiment.

First a pad oxide layer 12 formed from silicon dioxide (SiO₂) and a Si₃N₄ layer 13 formed from silicon nitride (Si₃N₄) are formed on an Si substrate 11 made from silicon (see FIG. 4A). More specifically, the provided Si substrate 11 is cleaned with an acidic cleaning liquid, and then, after rinsing the Si substrate 11 with pure water, the Si substrate 11 is dried. After the drying process has been completed the Si substrate 11 is placed in an oxidation furnace and subjected to a high temperature atmosphere of about 900° C., causing the Si to react with oxygen (O₂) and causing the pad oxide layer 12 to grow on the surface of the Si substrate 11. Then the Si₃N₄ layer 13 is formed on the pad oxide layer 12 by chemically reacting together silane (SiH₄) gas and ammonia (NH₃) gas in the gas phase (namely by Chemical Vapor Deposition (CVD)). The cross-section after forming the Si₃N₄ layer 13 is illustrated in FIG. 4A.

Then plural trenches 14 are formed so as to penetrate into the Si substrate 11 through the pad oxide layer 12 and the Si₃N₄ layer 13 (FIG. 4B). A photoresist is dripped onto the Si₃N₄ layer 13, and the Si substrate 11 is then spun at high speed (spin coating) so as to coat a thin film of resist thereon. Patterning of the resist thin film is then performed by illuminating a laser beam onto the resist thin layer. Dry etching is then performed using the patterned resist thin layer as a mask, and the trenches 14 are formed so as to penetrate into the Si substrate 11 through the pad oxide layer 12 and the Si₃N₄ layer 13. The resist thin layer remaining on the Si₃N₄ layer 13 is then removed using oxygen plasma, and the Si substrate 11 that has been subjected to the above processes is the washed in acid.

The portions of the Si substrate 11 not formed with the trenches 14 configure element forming regions for forming semiconductor elements. The separation distance between the adjacent trenches 14 is accordingly different for each size of semiconductor element. For example, in FIG. 4B separation distances are shown as width W1<width W2. The width of one of the trenches 14 may also be set wider than the width of another of the trenches 14 in consideration of the need to raise the insulating properties to adjacent semiconductor elements and other design matters of the semiconductor device configured by the semiconductor elements. For example, in FIG. 4B, widths of trenches are shown with W3>width W4.

A trench lining oxide layer 15 is then formed from silicon dioxide on the side and bottom faces of respective trenches 14 (FIG. 4C). More specifically, the Si substrate 11 is subjected to a high temperature oxygen atmosphere, causing thermal oxidization of the Si exposed at the side and bottom faces of each of the trenches 14, and forming the trench lining oxide layer 15.

An in-fill oxide layer 16 is then formed from silicon dioxide so as to fill the trenches 14 and cover the Si₃N₄ layer 13 (FIG. 4D). More specifically, silicon dioxide is deposited in the trenches 14 and on the Si₃N₄ layer 13 with SiH₄ and O₂ gases using a High Density Plasma-Chemical Vapor Deposition (HDP-CVD) method, thereby forming the in-fill oxide layer 16. Indented portions 16a and protruding portions 16b are formed at this stage on the surface of the in-fill oxide layer 16 due to the silicon dioxide being deposited simultaneously in the internal portions of the trenches 14 and on the Si₃N₄ layer 13. In the first exemplary embodiment the width of the Si₃N₄ layer 13 formed on the element forming regions of width W1 is narrower than the width of other parts of the Si₃N₄ layer 13. Due to the trench 14 of width W3 being adjacent to the element foaming region of width W1, it becomes difficult to deposit silicon dioxide on the element forming region of width W1, and the protruding portion 16b on the element forming region of width W1 is accordingly lower in height than the protruding portions 16h on the other element forming regions.

The in-fill oxide layer 16 is then subjected to polishing using a Chemical Mechanical Polishing (CMP) method, making the protruding portions 16b of the in-fill oxide layer 16 smaller (FIG. 4E). More specifically, polishing is performed using a ceria slurry (first polishing agent) with a ratio of 0.3 of ceria particles (CeO₂) to dispersion medium (additive agent) (referred to below as dispersion medium/ceria particle mixing ratio). Polyoxylate is employed as the dispersion medium. The amount of polishing may be appropriately adjusted within a range in which the in-fill oxide layer 16 (namely the protruding portions 16b) over the Si₃N₄ layer 13 are not eliminated. Preferably the film thickness of the in-fill oxide layer 16 on the Si₃N₄ layer 13 is as thin as possible. For example, polishing is preferably performed such that the film thickness of the in-fill oxide layer 16 on the Si₃N₄ layer 13 is about 700 nm or less. The polishing process just described is referred to as the first polishing process.

In the present exemplary embodiment, due to setting a dispersion medium/ceria particle mixing ratio of less than 0.5, the ratio of the polishing speed for the in-fill oxide layer to the polishing speed of the nitride layer (=in-fill oxide layer polishing speed/nitride layer polishing speed), namely the in-fill oxide layer to nitride layer polishing selectivity ratio, is small but the polishing speed is not reduced even when the film thickness of the SiO₂ layer is increased. The in-fill oxide layer to nitride layer polishing selectivity ratio is also sometimes referred to below simply as the oxide layer/nitride layer selectivity ratio. Due to performing the current process within a range in which the Si₃N₄ layer 13 is not exposed, the problem of the Si₃N₄ layer 13 being locally eliminated does not arise even with a relatively small oxide layer/nitride layer selectivity ratio.

The in-fill oxide layer 16 is then subjected to polishing with a CMP method, thereby flattening the in-fill oxide layer 16 (FIG. 4F). More specifically, polishing is performed using a ceria slurry (second polishing agent) with dispersion medium/ceria particle mixing ratio of 0.8, so as to remove all of the in-fill oxide layer 16 on the Si₃N₄ layer 13 (namely all of the protruding portions 16b), and flatten the exposed face of the in-fill oxide layer 16 and the Si₃N₄ layer 13. This processing process is referred to as the second polishing process.

In the present exemplary embodiment the dispersion medium/ceria particle mixing ratio is set at 0.5 or greater so as to achieve a relatively large oxide layer/nitride layer selectivity ratio. The Si₃N₄ layer 13 accordingly functions as a CMP stopper layer, and the Si₃N₄ layer 13 is not worn away. Due to setting the dispersion medium/ceria particle mixing ratio to 0.5 or greater there might have been some concern regarding lowering of the polishing speed, however since the film thickness of the in-fill oxide layer 16 has already been made thinner by the above first polishing process (for example to 700 nm or less), the polishing speed does not readily fall and the exposed face of the in-fill oxide layer 16 and the Si₃N₄ layer 13 can be readily flattened with high precision.

Note that the first polishing process and the second polishing process may be performed in succession to each other in the same machine. Adopting such an approach enables process savings to be made, such as in the time for removing the Si substrate 11 and time to change over the polishing agent, thereby achieving a reduction in the manufacturing time.

A portion of the in-fill oxide layer 16 is then removed by hydrogen fluoride (HF) etching (FIG. 4G). In the present exemplary embodiment the film thickness of the in-fill oxide layer 16 filled in each of the trenches 14 is thinned such that the side faces of the pad oxide layer 12 are not exposed in the trench 14. Etching may be performed to the extent that the side faces of the pad oxide layer 12 are exposed in the trench 14, however preferably etching is performed to a range in which the trench lining oxide layer 15 are not exposed in the trench 14.

All of the Si₃N₄ layer 13 is then removed by processing with hot phosphoric acid (FIG. 4H). A portion of the pad oxide layer 12 and the in-fill oxide layer 16 is then removed by re-etching with hydrogen fluoride, flattening the surface of the Si substrate 11 (FIG. 4I). This completes the formation of element isolation layers 20 from the trench lining oxide layer 15 and the in-fill oxide layer 16.

According to the method of forming the element isolation layer of the present exemplary embodiment, the in-fill oxide layer 16 filled in the trenches 14 and formed over the Si₃N₄ layer 13 is polished in a two stage process, and then flattening of the in-fill oxide layer 16 and the Si₃N₄ layer 13 is performed. In the two stage polishing process, the oxide layer/nitride layer selectivity ratio of the ceria slurry is set larger in the later performed second polishing process than the oxide layer/nitride layer selectivity ratio of the previously performed first polishing process. Such a two stage polishing process enables the in-fill oxide layer 16 to be prevented from remaining on the Si₃N₄ layer 13 and the Si₃N₄ layer 13 to be prevented from being worn away. Namely, controllability of the polishing process of the in-fill oxide layer 16 formed on the semiconductor substrate 11 is raised, and an element isolation layer 20 with excellent element isolation properties can be formed.

In the above exemplary embodiment the dispersion medium/ceria particle mixing ratio in the first polishing process is set at less than 0.5, and the dispersion medium/ceria particle mixing ratio in the second polishing process is set at 0.5 or greater, however there is no limitation thereto. The mixing ratios may be appropriately adjusted such that the oxide layer/nitride layer selectivity ratio of the second polishing process is greater than the oxide layer/nitride layer selectivity ratio of the first polishing process.

### Second Exemplary Embodiment

In the first exemplary embodiment the first polishing process is performed using a ceria slurry with a dispersion medium/ceria particle mixing ratio of less than 0.5 (specifically 0.3) however the first polishing process may be performed using other polishing agents. Explanation follows regarding a first polishing process employing a different polishing agent to that of the first exemplary embodiment. Since other parts of the processing are similar to those of the first exemplary embodiment further explanation thereof is omitted.

In the first polishing process of a second exemplary embodiment, the protruding portions 16b of the in-fill oxide layer 16 are made smaller by a CMP method employing a silica slurry as the polishing agent with silica particles formed from SiO₂. Similarly to in the first exemplary embodiment, the amount of polishing can be appropriately adjusted to a range in which the in-fill oxide layer 16 (namely the protruding portions 16b) on the Si₃N₄ layer 13 is not eliminated (namely a range in which the Si₃N₄ layer 13 is not exposed). The film thickness of the in-fill oxide layer 16 on the Si₃N₄ layer 13 is preferably made as thin as possible, for example polishing is preferably performed so as to make the film thickness 700 nm or less for the in-fill oxide layer 16 on the Si₃N₄ layer 13.

In the present exemplary embodiment, the oxide layer/nitride layer selectivity ratio is comparatively small due to employing a silica slurry, however there is no fall in the polishing speed even when the film thickness of the SiO₂ layer is increased. Since polishing is performed in this process to within a range in which the Si₃N₄ layer 13 is not exposed, problems of the Si₃N₄ layer 13 being locally eliminated do not occur even though the oxide layer/nitride layer selectivity ratio is small.

Accordingly, even though a different type of polishing agent is employed, similar effects can be obtained to those of the first exemplary embodiment as long as in the first polishing process and the second polishing process the oxide layer/nitride layer selectivity ratio of the polishing agent employed in the second polishing process is set greater than the oxide layer/nitride layer selectivity ratio of the polishing agent employed in the first polishing process.

### Third Exemplary Embodiment

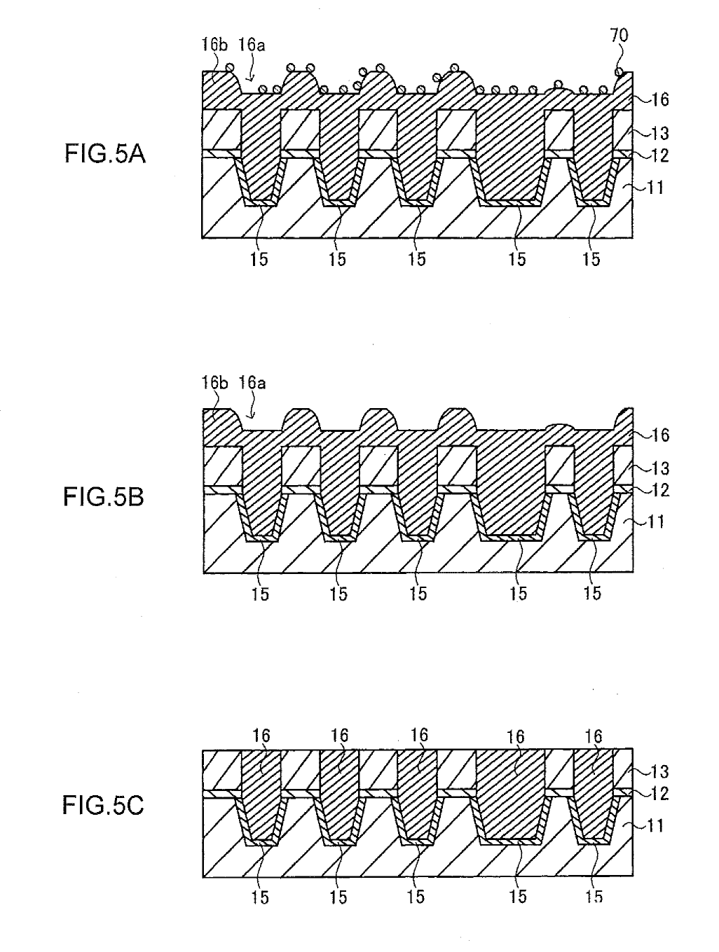

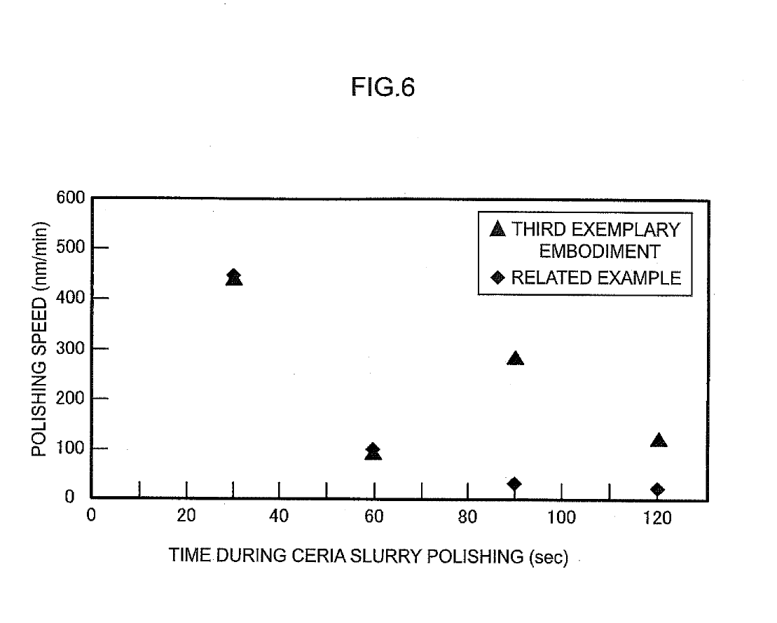

In both the first exemplary embodiment and the second exemplary embodiment polishing is performed with the ceria slurry being continuously fed in without interruption for the second polishing process employing ceria slurry, however there is no limitation thereto. For example, polishing may be performed while another solvent is temporarily fed in place of the ceria slurry. Explanation follows regarding another second polishing process, with reference to FIG. 5A to FIG. 5C, and FIG. 6. FIG. 5A to FIG. 5C are cross-sections for explaining the other second polishing process employing ceria slurry, and FIG. 6 is a graph illustrating relationships of polishing speed against time during polishing for the second polishing process according to both a third exemplary embodiment and a related polishing process. Since other parts of the processing are similar to those of the first exemplary embodiment the same reference numerals are appended and further explanation thereof is omitted.

After the first polishing process, polishing is then performed for 60 seconds while supplying a ceria slurry of dispersion medium/ceria particle mixing ratio 0.8 onto the polishing face. After this polishing process has been performed there is still in-fill oxide layer 16 remaining on the Si₃N₄ layer 13 (FIG. 5A). In this polishing process the polishing speed reduces as the polishing time elapses due to employing the ceria slurry of dispersion medium/ceria particle mixing ratio 0.8. As shown in FIG. 6, the polishing speed is about 450 nm/min at 30 seconds elapsed from the start of polishing, however at 60 seconds elapsed from the start of polishing the polishing speed has fallen to 100 nm/min. The reason for this is that, as shown in FIG. 5A, the dispersion medium 70 contained in the ceria slurry is adhered onto the in-fill oxide layer 16 (namely onto the polishing face).

Ceria slurry supply is stopped after 60 seconds have elapsed from the start of polishing, and polishing is performed for 10 seconds while pure water is being supplied onto the polishing face in place of the ceria slurry. Polishing of the in-fill oxide layer 16 does not progress during this time with since there is no polishing agent supplied, however the dispersion medium 70 that has adhered onto the in-fill oxide layer 16 is washed away (FIG. 5B). Namely, the surface of the in-fill oxide layer 16 is washed by performing the polishing process with pure water. Such a polishing process is also sometimes referred to as water polishing or wash polishing.

After completing water polishing, polishing is then performed for 60 seconds while a ceria slurry of dispersion medium/ceria particle mixing ratio 0.8 is supplied onto the polishing face, resulting in total removal of the in-fill oxide layer 16 on the Si₃N₄ layer 13 (namely the protruding portions 16b), and flattening the exposed faces of the in-fill oxide layer 16 and the Si₃N₄ layer 13 (FIG. 5C). The polishing speed in this polishing process drops off as polishing time elapses due to employing the ceria slurry with dispersion medium/ceria particle mixing ratio 0.8, however since the dispersion medium 70 adhered onto the in-fill oxide layer 16 has previously been removed by the water polishing described above, the polishing speed when 30 seconds has elapsed since the end of water polishing (the time 90 seconds in FIG. 6) is about 300 nm/min, and the polishing speed when 60 seconds has elapsed since the end of water polishing (the time 120 seconds in FIG. 6) is about 150 nm/min. Namely it can be seen that there has been some recovery in the polishing speed due to performing the water polishing described above.

However, in a related polishing process in which water polishing is not performed as shown in FIG. 6, the polishing speed continues to fall as polishing time elapses. This is due to the dispersion medium 70 adhering onto the polishing face and impeding polishing by the ceria particles.

Polishing while supplying pure water in place of ceria slurry part way through the polishing process using ceria slurry, as described above, enables dispersion medium that has adhered to the polishing face to be removed, allowing polishing speed employing ceria slurry to subsequently recover.

While explanation has been given of a case in the above exemplary embodiment in which water polishing is employed during the second polishing process with the ceria slurry of dispersion medium/ceria particle mixing ratio 0.8, the water polishing described above may also be introduced during the first polishing process employing the ceria slurry of dispersion medium/ceria particle mixing ratio 0.3. There is also no limitation to employing pure water as the liquid supplied to remove the dispersion medium, and another washing liquid, such as an alcohol, may be employed. Configuration may also be made with the water polishing performed plural times during polishing process(es) using ceria slurry.

What is claimed is:

1. A method of forming an element isolation layer, the method comprising:
forming a pad oxide layer and a nitride layer in succession on a front face of a semiconductor substrate;
forming a trench so as to penetrate through the pad oxide layer and the nitride layer and into the semiconductor substrate;
forming an in-fill oxide layer so as to fill the trench and cover the nitride layer;
polishing the in-fill oxide layer using a first polishing agent so as to leave in-fill oxide layer remaining over the nitride layer; and
polishing the in-fill oxide layer using a second polishing agent having a polishing selectivity ratio of the in-fill oxide layer to the nitride layer greater than the polishing selectivity ratio of the first polishing agent, so as to expose the nitride layer and flatten the exposed faces of the nitride layer and the in-fill oxide layer.

2. The method of claim 1, wherein a polishing speed of the polishing employing the first polishing agent is larger than the polishing speed of the polishing process employing the second polishing agent.

3. The method of claim 2, wherein the first polishing agent is a ceria slurry with a mixing ratio of dispersion medium to ceria particles of less than 0.5, and the second polishing agent is a ceria slurry in which the mixing ratio is 0.5 or greater.

4. The method of claim 2, wherein the first polishing agent is a silica slurry, and the second polishing agent is a ceria slurry with a mixing ratio of dispersion medium to ceria particles of 0.5 or greater.

5. The method of claim 3, wherein the step for polishing the in-fill oxide layer employing the ceria slurry comprises a process of washing a polishing face of the in-fill oxide layer.

6. The method of claim 1, further comprising removing a portion of the in-fill oxide layer, the pad oxide layer and the nitride layer, and flattening the front face of the semiconductor substrate.
